(19) United States
(12) Patent Application Publication
(10) Pub. No.: US 2026/0269682 A1
(43) Pub. Date: Sep. 10, 2026

(54) MOTOR AND BEARING CURRENT MEASUREMENT SYSTEM INCLUDING THE SAME

(71) Applicants: HYUNDAI MOTOR COMPANY, SEOUL (KR); KIA CORPORATION, SEOUL (KR)

(72) Inventors: Sung Sik Kong, Hwaseong-si (KR); Byung Su Kim, Hwaseong-si (KR); Seung Ho Ahn, Hwaseong-si (KR); Dong Hwi Kim, Hwaseong-si (KR); Chan Song Lee, Hwaseong-si (KR); Sang In Lee, Hwaseong-si (KR); Seok Bae Moon, Hwaseong-si (KR); Jun Muk Jo, Hwaseong-si (KR); Hyun Ku Lee, Hwaseong-si (KR); Mi Yong Lee, Hwaseong-si (KR)

(73) Assignees: HYUNDAI MOTOR COMPANY, SEOUL (KR); KIA CORPORATION, SEOUL (KR)

(21) Appl. No.: 19/557,483

(22) Filed: Mar. 5, 2026

(30) Foreign Application Priority Data
Mar. 5, 2025 (KR) 10-2025-0028469

(51) Int. Cl. H02K 7/08; H02K 5/22; H02K 7/00; H02K 11/00; H02K 11/27

(52) U.S. Cl. CPC H02K 7/083; H02K 5/225; H02K 7/003; H02K 11/0094; H02K 11/27

(57) ABSTRACT

A motor is provided. The motor includes a housing, a shaft disposed in the housing and including a through-portion or channel, a rotor coupled to the shaft and rotating together with the shaft, a stator surrounding the rotor and supported by the housing, a bearing disposed between the shaft and the housing, and a bearing current measurement apparatus at least partially disposed in the through-portion. The bearing current measurement apparatus includes an antenna extending into the through-portion surrounded by the bearing.

### CROSS-REFERENCE TO RELATED APPLICATION(S)

This application claims benefit of priority to Korean Patent Application No. 10-2025-0028469 filed on Mar. 5, 2025 in the Korean Intellectual Property Office, the disclosure of which is incorporated herein by reference in its entirety.

### TECHNICAL FIELD

The present disclosure relates to a motor and a bearing current measurement system.

### BACKGROUND

A driving motor may be used as a device in various industrial fields such as manufacturing, energy, and transportation. A bearing may support a rotating component of the motor to minimize friction and maintain the performance and reliability of the motor. However, in an inverter-based motor control system, an electrochemical current may occur in a bearing portion of the motor, which may cause bearing damage. As a result, abnormal noise, degradation of motor performance, malfunctioning, or the like may occur.

In one approach, a bearing state may be indirectly monitored by measuring a common mode voltage (CMV). However, the CMV is not entirely converted into the electrochemical current of the bearing portion, which may result in a limitation in accurately measuring the electrochemical current. In addition, direct measurement of the electrochemical current may incur high installation costs and technical complexity, which may make practical use in industrial sites challenging.

### SUMMARY

An example embodiment of the present disclosure is to provide a motor for (e.g., directly) measuring an electrochemical current flowing through a bearing, and a bearing current measurement system including the same.

Another example embodiment of the present disclosure is to provide a motor for facilitating measurement of the electrochemical current flowing through a bearing by reducing a physical distance between the motor and the bearing, and a bearing current measurement system including the same.

Another example embodiment of the present disclosure is to provide a motor in which an antenna for measuring an electrochemical current of a bearing may be installed without (e.g., requiring) a separate installation space, and a bearing current measurement system including the same.

According to an example embodiment of the present disclosure, a motor is provided. The motor includes a housing, a shaft disposed in the housing and including a through-portion (e.g., a channel), a rotor coupled to the shaft and rotating together with the shaft, a stator surrounding the rotor and supported by the housing, a bearing disposed between the shaft and the housing, and a bearing current measurement apparatus at least partially disposed in the through-portion. The bearing current measurement apparatus includes an antenna extending into the through-portion surrounded by the bearing.

The bearing current measurement apparatus may further include a wire electrically connected to the antenna, and the wire may be exposed outward from the housing.

The antenna may be disposed in the through-portion and spaced apart from the shaft.

The bearing current measurement apparatus may further include a connector connected to the antenna and supporting the antenna by being coupled to the housing.

The bearing current measurement apparatus may further include a connector connected to the antenna. The connector may be coupled to the housing, and the connector may include a thread formed on an outer surface thereof.

According to another example embodiment of the present disclosure, a bearing current measurement system is provided. The bearing current measurement system includes a motor and a data collection system electrically connected to the motor. The motor includes a housing, a shaft disposed in the housing and including a through-portion, a rotor coupled to the shaft and rotating, a stator surrounding the rotor and supported by the housing, a bearing supporting the shaft, and a bearing current measurement apparatus at least partially disposed in the through-portion. The bearing current measurement apparatus includes an antenna disposed in the through-portion and passing through a center of the bearing.

The bearing current measurement apparatus may further include a wire electrically connected to the antenna, and the wire may be connected to the data collection system.

The data collection system may be disposed outside the housing.

The bearing current measurement apparatus may further include a connector disposed between the antenna and the wire, and the connector may be coupled to the housing to support the antenna.

The bearing current measurement apparatus may further include a connector disposed between the antenna and the wire, the connector may be screw-coupled to the housing, and the connector may include a thread formed on an outer surface thereof.

### BRIEF DESCRIPTION OF DRAWINGS

The above and other example embodiments, features, and advantages of the present disclosure will be more clearly understood from the following detailed description, taken in conjunction with the accompanying drawings.

FIG. 1 is a perspective view illustrating a bearing current measurement system according to an example embodiment of the present disclosure.

FIG. 2 is a cross-sectional view illustrating a motor according to an example embodiment of the present disclosure.

FIG. 3 is an exploded perspective view illustrating a bearing current measurement apparatus according to an example embodiment of the present disclosure.

### DETAILED DESCRIPTION

The present disclosure may have various modifications and various example embodiments, and specific example embodiments will be illustrated in the drawings and described in detail. However, the scope of the present disclosure is not limited to specific example embodiments, and includes (e.g., all) modifications, equivalents, or substitutes included within the spirit and scope of the present disclosure.

Terms such as “first” or “second” may be used to describe various components, and the components are not to be construed as being limited by these terms. The terms are used (e.g., only) to distinguish one component and another component from each other. For example, a “first” component may be referred to as a “second” component and the “second” component may also be referred to as the “first” component, without departing from the scope of the present disclosure. A term “and/or” includes a combination of a plurality of related described items or any one of the plurality of related described items.

Terms such as “unit,” “part,” or “portion,” “units,” “parts,” or “portions,” may be used to describe various components, and the components should not be limited by these terms. The terms may refer to physically and/or visibly distinguishable components, and also may refer to components in which functions or configurations of the corresponding portions are described although separation or partition thereof is not (e.g., clearly) provided (e.g., defined).

Terms used in the present disclosure are used (e.g., only) to describe specific example embodiments and are not intended to limit the present disclosure. A term of a singular number may include its plural number unless the context (e.g., clearly) indicates otherwise. In the present disclosure, terms such as “include” or “have” are intended to designate that features, numbers, steps, operations, components, parts, or combinations thereof described in the specification are present, and do not preclude the presence or addition of one or more other features, numbers, steps, operations, components, parts, or combinations thereof.

Unless otherwise provided (e.g., defined), (e.g., all) terms used herein, including technical or scientific terms, have the same meaning as those generally understood by those skilled in the art to which the present disclosure pertains. Terms generally used and defined in dictionaries should be interpreted as having meanings consistent with those in the context of the related art, and should not be interpreted as having idealized or overly formal meanings unless explicitly defined in the present disclosure.

In the following description, terms related to directions, such as “front,” “rear,” “side,” “forward,” “backward,” “upper,” “lower,” “upward,” “downward,” “left,” and “right” are provided (e.g., defined) based on a motor MT. In addition, terms such as “first” and “second” may be used to describe various components; however, the components are not limited in order, size, position, or importance by such terms, and each term may be assigned (e. g, solely) for a purpose of distinguishing one component from another component.

Hereinafter, example embodiments of the present disclosure will be described in detail with reference to the accompanying drawings.

In the drawings, a direction D1 may be referred to as a first direction D1, a direction D2 (e.g., intersecting the first direction D1) may be referred to as a second direction D2, and a direction D3 (e.g., intersecting both the first direction D1 and the second direction D2) may be referred to as a third direction D3. The third direction D3 may be referred to as an upward direction, and a direction opposite to the third direction D3 may be referred to as a downward direction. Each of the first direction D1 and the second direction D2 may be referred to as a horizontal direction.

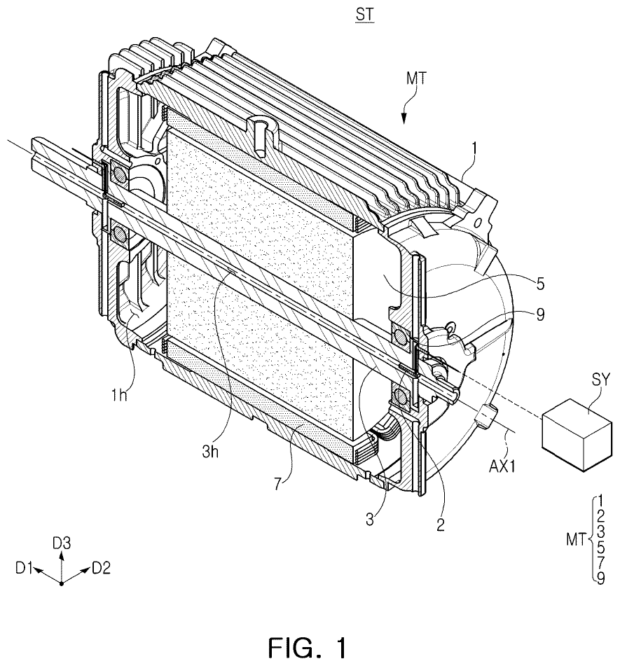

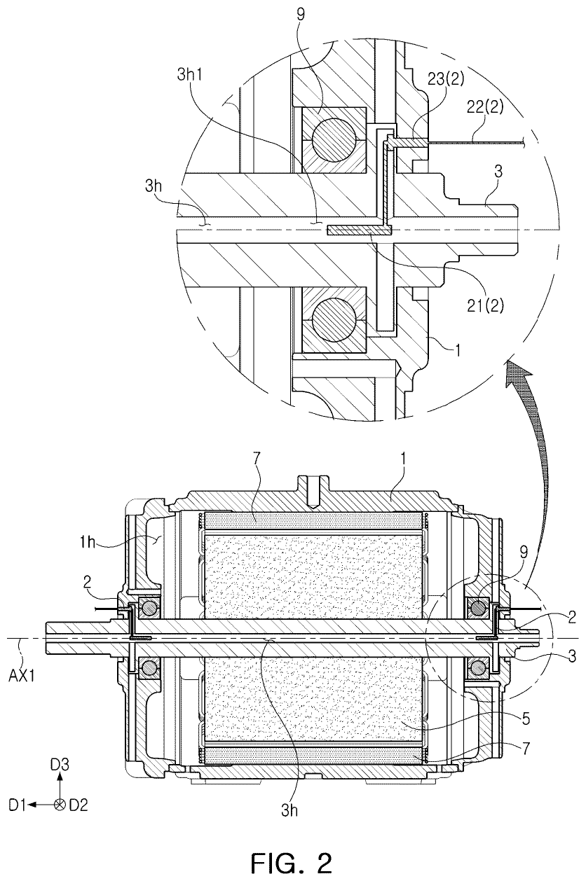

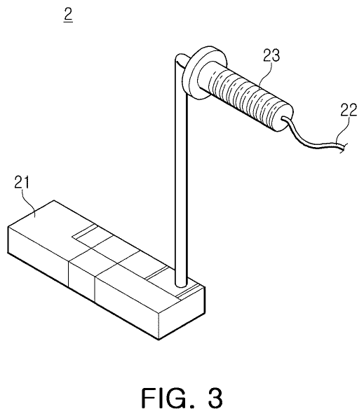

FIG. 1 is a perspective view illustrating a bearing current measurement system ST according to an example embodiment of the present disclosure, FIG. 2 is a cross-sectional view illustrating a motor MT according to an example embodiment of the present disclosure, and FIG. 3 is a perspective view illustrating a bearing current measurement apparatus 2 according to an example embodiment of the present disclosure.

Referring to FIGS. 1 and 2, a bearing current measurement system ST according to an example embodiment may include a motor MT and a data collection system SY. The motor MT according to an example embodiment may include a housing 1, a shaft 3, a rotor 5, a stator 7, a bearing 9, and a bearing current measurement apparatus 2.

The bearing current measurement system ST may measure a current flowing through a bearing 9. By measuring the current flowing through the bearing 9, the bearing current measurement system ST may predict (e.g., or determine) a degree of wear (e.g., progression) of the bearing 9. The bearing current measurement system ST may measure a bearing current that is a (e.g., direct) cause of damage to the bearing 9, thereby preventing or managing wear of the bearing 9.

The housing 1 may include an internal space 1h. The housing 1 may support the shaft 3, the stator 7, the rotor 5, the bearing 9, and the bearing current measurement apparatus 2. However, a structure of the motor MT supported by the housing 1 is not limited thereto. The housing 1 may have a cylindrical shape, and the shape of the housing 1 is not limited thereto. The housing 1 may have a first axis AX1 extending in the first direction D1 as a central axis.

The shaft 3 may pass through at least a portion of the housing 1. The shaft 3 may extend toward the internal space 1h. The shaft 3 may have the first axis AX1 as a central axis. The shaft 3 may extend toward the internal space 1h while having the first axis AX1 as the central axis. The shaft 3 may rotate while having the first axis AX1 as the central axis. The shaft 3 may include a through space. The shaft 3 may include a through-portion 3h. The through-portion 3h may extend in the first direction D1 while having the first axis AX1 as a central axis.

The stator 7 may be coupled to the housing 1. The stator 7 may be supported by the housing 1. The stator 7 may surround the rotor 5. The stator 7 may surround at least a portion of the shaft 3.

The stator 7 may include a core structure wound with coils. The core may be formed of a highly conductive magnetic material to minimize magnetic loss and may provide an (e.g., efficient) magnetic flux path. The core may have a slot structure for (e.g., substantially uniformly) distributing magnetic flux density.

The coils may include copper or aluminum wires. The coils may be (e.g., substantially uniformly) wound in each slot of the stator 7 to form a rotating magnetic field for driving the rotor through a three-phase alternating current. The coils may be covered with an insulating coating or insulating film to prevent or minimize short circuits.

However, the structure of the stator 7 is not limited thereto. The stator 7 may have a slotless structure (e.g., without slots), and may have various shapes. For example, the stator 7 may include permanent magnets.

The rotor 5 may rotate together with the shaft 3. The rotor 5 may rotate while being coupled to the shaft 3. The rotor 5 may surround at least a portion of the shaft 3. However, the coupling between the rotor 5 and the shaft 3 is not limited thereto.

The rotor 5, according to an example embodiment, may include a core. The rotor 5 according to an example embodiment may optionally include permanent magnets or coils. The permanent magnets may be attached to or embedded in the core of the rotor. A magnetic force may be generated between the permanent magnets of the rotor 5 and the permanent magnets of the stator 7 by an alternating magnetic field generated by the stator 7, thereby providing (e.g., enabling) rotational motion of the rotor 5. The permanent magnets may include at least one of neodymium (Nd), iron (Fe), boron (B), samarium, cobalt, alnico, or ferrite, and the material of the permanent magnets is not limited thereto.

The coil may be wound around the core of the rotor 5. The coil may generate an induced current inside the rotor and may interact with the magnetic field generated by the stator 7. The coil may include copper (Cu); however, the type of conductive coil is not limited thereto.

The rotor 5 may rotate by interacting with the stator 7. For example, when an alternating current is supplied to the stator 7, a change in the magnetic field may be generated due to a change in a current flowing through the stator 7. Due to the change in the magnetic field generated by the stator 7, an induced current may be generated in the rotor 5. An electromagnetic force may be generated in the rotor 5, and thus, the rotor 5 may rotate. In addition, when a direct current is supplied to the rotor 5, the rotor 5 may receive an electromagnetic force in the magnetic field formed by the stator 7 and rotate. For example, the rotor 5 may (e.g., optionally) include a commutator to change a direction of a current flowing in the same direction.

The bearing 9 may support the shaft 3. The bearing 9 may be disposed between the shaft 3 and the housing 1. The bearing 9 may connect the shaft 3 to the housing 1. The bearing 9 may allow the shaft 3 to rotate relative to the housing 1. A plurality of bearings 9 may be provided. However, herein, the plurality of bearings 9 may be described as a single bearing. The bearing 9 may surround at least a portion of the shaft 3. The bearing 9 may surround at least a portion of a through-portion 3h inside the shaft 3. For example, the through-portion 3h may include a bearing through-portion 3h1 disposed at the center of the bearing 9. A plurality of bearing through-portions 3h1 may be provided. However, herein, the plurality of bearing through-portions 3h1 are described as a single bearing through-portion. The bearing through-portion 3h1 may pass through the center of the bearing.

When the rotor 5 rotates, an electromagnetic field may be generated, and a voltage may thus be induced between the shaft 3 and structures surrounding the shaft 3. Due to the induced voltage, a current may flow along a discharge path. When the current generated by the induced voltage flows through the bearing 9, the bearing current may flow.

When the bearing current flows through the bearing 9, discharge may occur, and minute pits may be formed on a metal surface of the bearing 9. In addition, a (e.g., high-temperature) environment may be generated due to (electrical) discharge on the surface of the bearing 9, and lubricant may be impacted (e.g., damaged), thereby increasing friction between the bearing 9 and the shaft 3 and friction inside the bearing 9. As the surface of the bearing 9 is impacted (e.g., damaged), vibration may be induced, and performance of the bearing 9 may be degraded. Accordingly, when the bearing current flows through the bearing 9, the performance of the bearing 9 may be degraded, and/or a lifespan of the bearing 9 may be reduced, which may lead (e.g., expand) to a defect in the (e.g., entire) motor MT.

The bearing current measurement apparatus 2 may (e.g., directly) measure the bearing current. The bearing current measurement apparatus 2 according to an example embodiment may include an antenna 21. The bearing current measurement apparatus 2, according to an example embodiment, may optionally include a wire 22 and a connector 23.

The antenna 21 may be disposed in the through-portion 3h. The antenna 21 may extend into the through-portion 3h surrounded by the bearing 9. The antenna 21 may be disposed in the bearing through-portion 3h1. The antenna 21 may be surrounded by the shaft 3. The antenna 21 may be disposed in the through-portion 3h and spaced apart from the shaft 3. The antenna 21 may pass through the center of the bearing 9. By disposing the antenna 21 in the bearing through-portion 3h1, the antenna 21 may measure a current flowing through the bearing 9.

The wire 22 may be electrically connected to the antenna 21. The wire 22 may be extend outward of (e.g., from) the housing 1 and may be exposed outside of the housing 1. The wire 22 may be electrically connected to the data collection system SY.

In FIGS. 2 and 3, the connector 23 may be disposed between the antenna 21 and the wire 22. The connector 23 may connect the wire 22 to the antenna 21. The connector 23 may support the antenna 21. For example, referring to FIG. 2, the connector 23 may be coupled to the housing 1. The connector 23 may support the antenna 21 by being coupled to the housing 1. In other words, the connector 23 is coupled to the housing 1 to support the antenna 21. The connector 23 may be screw-coupled to the housing 1. Referring to FIG. 3, the connector 23 may include a thread formed on an outer surface thereof. In other embodiments, the connector 23 may be coupled to a separate external device disposed outside the housing 1, and the connector 23 may be coupled to the separate external device to support the antenna 21.

The data collection system SY may be electrically connected to the antenna 21. The data collection system SY, according to an example embodiment, may include a data acquisition (DAQ) device and a computer, such that, for example, the system may collect and/or evaluate an electrical discharge to determine if the discharge is greater than or less than a (e.g., predetermined) limit and then a decision can be made on the performance and/or reliability of the bearing and/or the motor. The DAQ device may convert a physical signal into a digital data to allow the computer to process or store the digital data. According to an example embodiment, the DAQ device may (e.g., optionally) include a signal conditioning device, a converter, a digital input/output device, or a communication interface. The signal conditioning device may convert a signal detected from the bearing current measurement apparatus 2 into a form processable by the DAQ device. The signal conditioning device may amplify, filter, and/or convert the signal detected from the bearing current measurement apparatus 2, or the like. The converter may convert an analog signal into a digital signal. The digital input/output device may collect digital data or transmit command signals. The communication interface may transmit and receive data to and from the DAQ device and the computer. The computer may receive data from the DAQ device and then process and visualize the data, such as plotting a discharge and a time, for example, on a graph. The data collection system SY may be disposed outside the housing 1.

The motor MT and the bearing current measurement system ST including the same, according to the example embodiments of the present disclosure, may facilitate management of the bearing 9 by (e.g., directly) measuring the bearing current. Electrochemical corrosion occurring in the bearing 9 may be related to a lifespan of the bearing 9, to a degree of wear of the bearing 9, and/or to a lifespan of the entire motor MT. Accordingly, the bearing current may need to be (e.g., continuously) managed. The bearing current measurement system ST may (e.g., continuously) observe, record, and analyze the bearing current to determine the wear and corrosion occurring in the bearing 9. Accordingly, the bearing current measurement system ST may facilitate the management of the bearing 9 and improve (e.g., enhance) safety of the motor.

According to the example embodiments of the present disclosure, the motor MT and the bearing current measurement system ST including the same may allow the bearing current measurement apparatus 2 to be installed in the motor MT without securing a separate installation space for the bearing current measurement apparatus 2. The bearing current measurement apparatus 2 may include the antenna 21 disposed in the through-portion 3h of (e.g., inside) the shaft 3. The antenna 21 may be supported by the connector 23 coupled to the housing 1. However, in other embodiments, the connector 23 may or may not be coupled to the housing 1, and may be coupled to a separate external device to support the antenna 21. The bearing current may be measured without designing or modifying a structure of the motor MT, thereby facilitating installation of the bearing current measurement apparatus 2, and increasing economic efficiency.

As set forth above, according to an example embodiment of the present disclosure, the motor and the bearing current measurement system including the same may (e.g., directly) measure an electrochemical current flowing through the bearing.

According to an example embodiment of the present disclosure, the motor and the bearing current measurement system including the same may facilitate measurement of an electrochemical current flowing through the bearing by reducing the physical distance between the motor and the bearing.

According to an example embodiment of the present disclosure, the motor and the bearing current measurement system including the same may allow an antenna for measuring an electrochemical current of the bearing to be installed without (e.g., requiring) a separate installation space.

While the example embodiments have been shown and described above, it will be apparent to those skilled in the art that modifications and variations could be made without departing from the scope of the present disclosure as provided (e.g., defined) by the appended claims.

What is claimed is:

1. A motor comprising:
a housing;
a shaft disposed in the housing, wherein the shaft includes a channel;
a rotor coupled to the shaft and configured to rotate with the shaft;
a stator surrounding the rotor, wherein the stator is supported by the housing;
a bearing disposed between the shaft and the housing; and
a bearing current measurement apparatus at least partially disposed in the channel,
wherein the bearing current measurement apparatus includes an antenna extending into the channel surrounded by the bearing.

2. The motor according to claim 1, wherein the bearing current measurement apparatus further includes a wire.

3. The motor according to claim 2, wherein the wire is electrically connected to the antenna.

4. The motor according to claim 3, wherein the wire extends outward from the housing.

5. The motor according to claim 1, wherein the antenna is disposed in the channel and the antenna is spaced apart from the shaft.

6. The motor according to claim 1, wherein the bearing current measurement apparatus further includes a connector connected to the antenna.

7. The motor according to claim 6, wherein the connector supports coupling the antenna to the housing.

8. The motor according to claim 1, wherein the bearing current measurement apparatus further includes a connector connected to the antenna,
the connector is coupled to the housing, and
the connector includes a thread formed on an outer surface of the connector.

9. A bearing current measurement system comprising:
a motor; and
a data collection system electrically connected to the motor,
wherein the motor includes:
a housing;
a shaft disposed in the housing, wherein the shaft includes a channel;
a rotor coupled to the shaft and configured to rotate;
a stator surrounding the rotor, wherein the stator is supported by the housing;
a bearing supporting the shaft; and
a bearing current measurement apparatus at least partially disposed in the channel, and
the bearing current measurement apparatus includes an antenna disposed in the channel and passing through a center of the bearing.

10. The system according to claim 9, wherein the bearing current measurement apparatus further includes a wire electrically connected to the antenna.

11. The system according to claim 10, wherein
the wire is connected to the data collection system.

12. The system according to claim 11, wherein the data collection system is disposed outside the housing.

13. The system according to claim 10, wherein the bearing current measurement apparatus further includes a connector disposed between the antenna and the wire.

14. The system according to claim 13, wherein
the connector is coupled to the housing to support the antenna.

15. The system according to claim 10, wherein the bearing current measurement apparatus further includes a connector disposed between the antenna and the wire, and the connector is coupled to the housing.

16. The system according to claim 15, wherein the connector includes a thread formed on a radially outer surface of the connector to facilitate coupling.
